(19) United States
(12) Patent Application Publication
(10) Pub. No.: US 2025/0391742 A1
(43) Pub. Date: Dec. 25, 2025

(54) COAXIAL SEMICONDUCTOR PACKAGE

(71) Applicant: VIRGINIA TECH INTELLECTUAL PROPERTIES, INC., Blacksburg, VA (US)

(72) Inventors: Mark Cairnie, Orwigsburg, PA (US); Jack Knoll, Arlington, VA (US); Christina DiMarino, Arlington, VA (US)

(21) Appl. No.: 19/245,692

(22) Filed: Jun. 23, 2025

Related U.S. Application Data
(60) Provisional application No. 63/662,599, filed on Jun. 21, 2024.

(51) Int. Cl. H01L 23/492

(52) U.S. Cl. CPC H01L 23/492

(57) ABSTRACT

Various embodiments related to coaxial semiconductor packages are described. In an example embodiment, a coaxial semiconductor package is comprised of a pair of stacked, annular, metal contacts, with a circular arrangement of switching transistors between the annular contacts, and where the switching transistors can be arranged concentrically with and electrically coupled to the metal, annular contacts. A gate interconnect can be configured with a coaxial electrical interconnect passing through the metal, annular contacts, and interfaced with a gate and a source of a switching transistor. Multiple coaxial semiconductor packages can be arranged concentrically, nested within one another, for bridge switch configurations, or stacked for series connected or back-to-back switch configurations.

### CROSS-REFERENCE TO RELATED APPLICATIONS

This application claims the benefit of and priority to U.S. Provisional Patent Application No. 63/662,599, filed Jun. 21, 2024, entitled “COAXIAL SEMICONDUCTOR PACKAGE,” the entire content of which is hereby incorporated herein by reference in its entirety.

### STATEMENT REGARDING FEDERALLY SPONSORED RESEARCH OR DEVELOPMENT

This invention was made with government support under grant number DE-AR0001568, awarded by ARPA-E. The government has certain rights in the invention.

### BACKGROUND

Power semiconductor packages provide an electrical and thermal interface between the power semiconductor device and the other components in a power converter while ensuring the electrical, thermal, and mechanical reliability of the power semiconductor. Power semiconductor packaging technology which utilizes ceramic and organic substrates for electrical isolation are limited in their ability to scale to high voltages. Press-pack style packages for gate turn-off thyristors (GTOs), silicon controlled rectifiers (SCRs), and insulated gate bipolar transistors (IGBTs) circumvent this limitation by omitting the substrate, thus leaving the electrical isolation to be dealt with at the system level. However, press-packs rely on dry contacts, that while cost effective: a) hinder double-sided cooling, b) necessitate costly hermetic seals to contain gas encapsulation, and c) impose a strict pressure uniformity requirement. Furthermore, it is difficult to use press-pack modules in switch arrangements such as bridges without introducing significant commutation inductance, which poses a serious limitation for high-frequency power applications.

### BRIEF DESCRIPTION OF THE DRAWINGS

Many aspects of the present disclosure can be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views.

FIG. 1 depicts a perspective view of an example coaxial semiconductor package according to one or more embodiments of the present disclosure.

FIG. 2 depicts a perspective view of a switch package in the coaxial semiconductor package shown in FIG. 1, according to one or more embodiments of the present disclosure.

FIG. 3 depicts an exploded view of the coaxial semiconductor package shown in FIG. 1, according to one or more embodiments of the present disclosure.

FIG. 4 depicts a perspective view of a metal interconnect used in the switch package shown in FIGS. 2 and 3 according to one or more embodiments of the present disclosure.

FIG. 5 depicts a perspective view of a nested coaxial semiconductor package according to one or more embodiments of the present disclosure.

FIG. 6 depicts an input switch package of the nested coaxial semiconductor package shown in FIG. 5 according to one or more embodiments of the present disclosure.

FIG. 7 depicts an output switch package of the nested coaxial semiconductor package shown in FIG. 5 according to one or more embodiments of the present disclosure.

FIG. 8 depicts a coaxial commutation loop in the nested coaxial semiconductor package shown in FIG. 5 according to one or more embodiments of the present disclosure.

FIG. 9 depicts an inter-package schematic in the nested coaxial semiconductor package shown in FIG. 5 according to one or more embodiments of the present disclosure.

FIG. 10 depicts an intra-package schematic of the nested coaxial semiconductor package shown in FIG. 5 according to one or more embodiments of the present disclosure.

FIG. 11 depicts a schematic of a coaxial semiconductor package that can be implemented in the nested coaxial semiconductor package shown in FIG. 5, according to one or more embodiments of the present disclosure.

FIG. 12 depicts a perspective view of a coaxial gate interconnect according to one or more embodiments of the present disclosure.

### DETAILED DESCRIPTION

Power semiconductor package architectures are often limited to a specific system voltage range and generally need to be completely redesigned to meet the needs of a higher voltage system. For example, spacing between pads, interconnects, and leads may need to be increased at minimum and more extreme measures may be required to maintain a sufficiently low peak electric field. Due to triple points that often exist in power semiconductor packages, these issues scale exponentially with voltage and quickly become unmanageable. Current power semiconductor packaging technology can also limit manufacturability and increase cost. For example, some semiconductor packages may include molybdenum posts for electrical connection of switching transistors, which can be costly to incorporate in practice. Additionally, molybdenum posts can create stack-up tolerance issues. Instead of molybdenum posts, other semiconductor packages may include solid copper posts. However, solid copper posts can also create stack-up tolerance issues, coefficient of thermal expansion (CTE) mismatch, and structural rigidity. Other semiconductor packages incorporating switching transistors may utilize gate interconnects for electrical connection. However, these gate interconnects may be wire bonds, which can be mechanically limiting in length (e.g., vertical height). These gate interconnects may also be posts, which can include multiple bonds and cause inductance to scale poorly with length.

In the context outlined above, one or more embodiments can include a coaxial semiconductor package, which includes a first concentric metal contact and a plurality of switching transistors arranged concentrically at and around the first concentric metal contact. A switching transistor of the plurality of switching transistors includes a source coupled (e.g., bonded, mechanically coupled, and/or electrically coupled, etc.) to a metal interconnect, a drain coupled (e.g., bonded, mechanically coupled, and/or electrically coupled, etc.) to the first concentric metal contact, and a gate coupled (e.g., bonded, mechanically coupled, and/or electrically coupled, etc.) to a coaxial gate interconnect. The coaxial gate interconnect can be configured to couple (e.g., bonded, mechanically coupled, and/or electrically coupled, etc.) the switching transistor to a gate driver of a power converter system. The coaxial semiconductor package further includes a second concentric metal contact coupled to the source. The embodiments combine the voltage scaling benefit of substrate-less packaging with wetted contacts which a) enables the use of high-dielectric-strength encapsulation materials, b) alleviates the uniform pressure requirement, and c) allows for more effective double-sided cooling. In addition, the technology utilizes coaxial nesting of switch packages to allow for very low commutation loop inductance and improved module-to-module voltage scaling.

In one or more embodiments, a coaxial semiconductor package can be comprised of a pair of stacked, annular, metal contacts, with a circular arrangement of switching transistors between the annular contacts, and where the switching transistors can be arranged concentrically with and electrically coupled to the metal, annular contacts. A gate interconnect can be configured with a coaxial electrical interconnect passing through the metal, annular contacts, and interfaced with a gate and source of a switching transistor. Multiple coaxial semiconductor packages can be arranged concentrically, nested within one another, for bridge switch configurations, or stacked for series connected or back-to-back switch configurations.

A coaxial semiconductor package according to the embodiments can be incorporated within medium voltage (MV) cables for use in distribution-scale substations, among others, for power distribution and power conversion. For example, other possible applications for the coaxial semiconductor package include electric vehicle (EV) charging and renewable energy infrastructure. The coaxial semiconductor package of the embodiments can include many benefits over conventional semiconductor packages that may be incorporated within MV cables, such as inclusion of thermo-mechanical and mechanically rugged features, which can enable the coaxial semiconductor package to withstand and survive high temperatures and mechanical stress such as axial loading.

The coaxial semiconductor package of the embodiments can further allow for seamless integration with MV cables and provide benefits such as balanced current distribution, axially symmetric heat distribution, and reduced peak electric field intensity. The coaxial semiconductor package can include slip ring electrical contacts, compliant copper interconnects, aluminum nitride (AlN) spacers, and coaxial gate and/or source interconnects, among other components. The slip ring electrical contacts can facilitate blind electrical connections, mechanical compliance, and axial symmetry. The compliant copper interconnects can absorb stack-up tolerances, which can improve yield and allow for a fully silver (Ag) sintered package. The AIN spacers can promote double sided cooling and improve mechanical ruggedness while maintaining electrical isolation between a drain and a source. Additionally, the coaxial gate interconnects can facilitate reduced gate loop inductance which can aid in reduced gate voltage overshoots and gate voltage ringing.

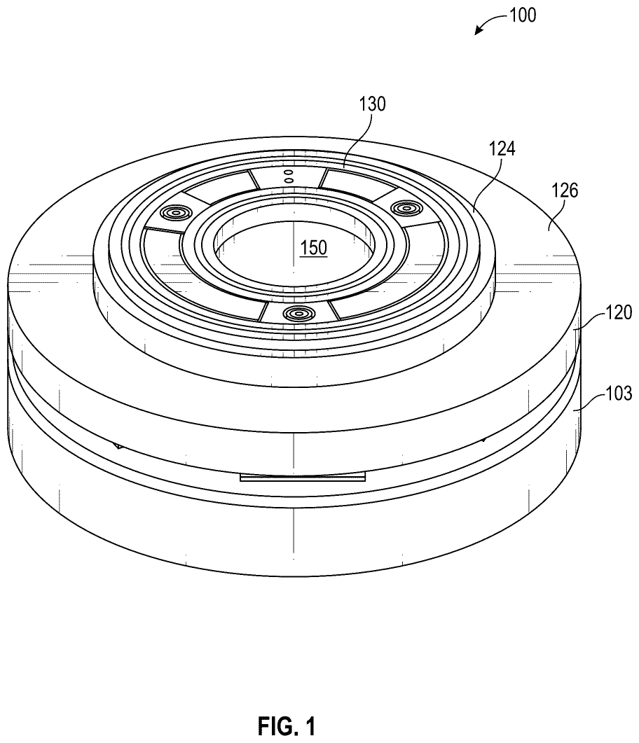

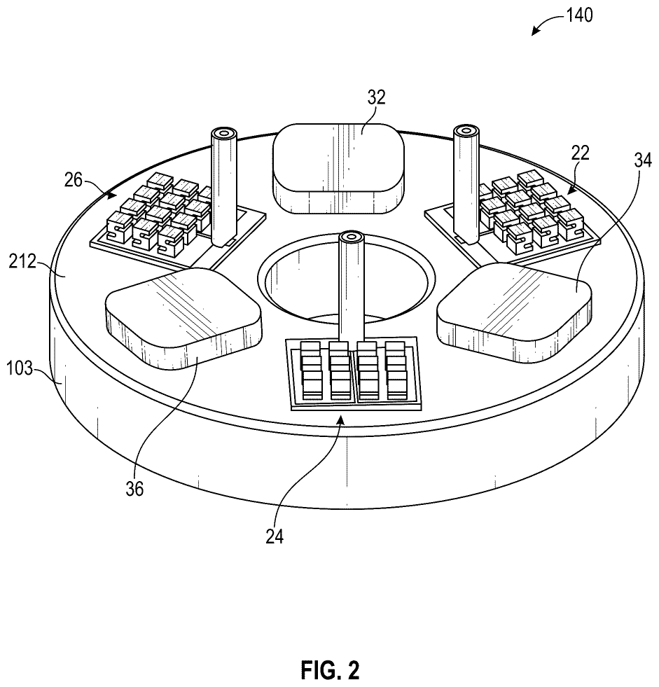

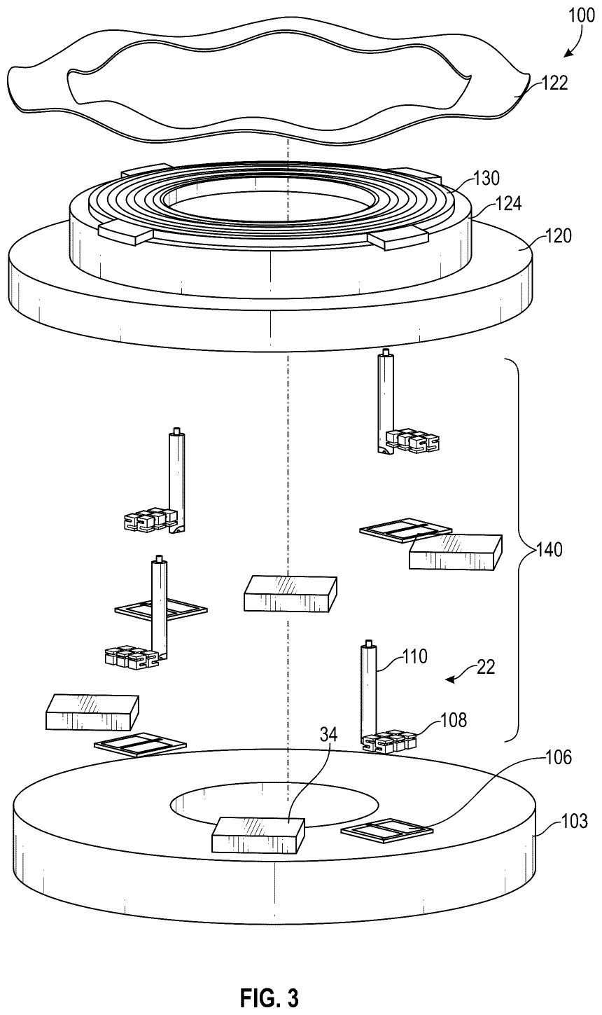

Turning now to the drawings, FIG. 1 depicts a perspective view of an example coaxial semiconductor package 100, FIG. 2 depicts a perspective view of a switch package in the coaxial semiconductor package 100 shown in FIG. 1, and FIG. 3 depicts an exploded view of the coaxial semiconductor package 100 shown in FIG. 1, according to one or more embodiments of the present disclosure. The coaxial semiconductor package 100 can be incorporated within MV cables for use in distribution-scale substations, among others, for power distribution and power conversion. Additionally, the coaxial semiconductor package 100 can be used for EV charging and power conversion in renewable energy infrastructure.

The coaxial semiconductor package 100 is not necessarily drawn to any particular scale or size. Additionally, FIGS. 1-3 are not exhaustively illustrated, meaning that other components that are not shown in FIGS. 1-3 can be included or relied upon in some cases. The coaxial semiconductor package 100 includes a first concentric metal contact 103, a second concentric metal contact 120, a printed circuit board (PCB) slip ring 130 on an upper portion 124 of the second concentric metal contact 120, and a wave spring 122 that can also be positioned around the upper portion 124 of the second concentric metal contact 120.

Referring to FIGS. 2 and 3, a switch package 140 can be positioned at the first concentric metal contact 103 and can include individual switches modules 22, 24, and 26 in addition to the second concentric metal contact 120. Although three switch modules 22, 24, and 26 are depicted, greater than or less than three switch modules can be implemented in the coaxial semiconductor package 100 based on power conversion requirements, application for the coaxial semiconductor package 100, die size of each of the switching transistors of the switch modules 22, 24, and 26, and dimensions of the metal contacts 103 and 120, among other factors. As depicted, the individual switch modules 22, 24, and 26 are arranged concentrically around an upper surface 212 of the concentric metal contact 103. Each switch module 22, 24, or 26 generally includes similar components, such as a die and various interconnects, and these components are described in further detail below.

The switch package 140 can also include spacers 32, 34, and 36, which are arranged concentrically around the upper surface 212. The spacer 32 is arranged between the switch modules 22 and 26, the spacer 34 is arranged between the switch modules 22 and 24, and the spacer 36 is arranged between the switch modules 26 and 24. Each of the spacers 32, 34, and 36 can be used to separate the first concentric metal contact 103 and the second concentric metal contact 120, and to adjust a height between the first concentric metal contact 103 and the second concentric metal contact 120. Each of the spacers 32, 34, and 36 can include AIN, but other materials and compositions can be relied upon.

The spacers 32, 34, and 36 can be substantially rectangular, square-like, or hexagonal in shape. In some cases, the spacers 32, 34, and 36 can include one or more rounded corners. A radius for the rounded corners can be set based on a compromise between reducing the maximum E-field and maximizing a bonding area. In other examples, the spacers 32, 34, and 36 can adopt other shapes more generally such as round, square or square-like, and rectangular or rectangular-like. Additionally, a variety of different metallization schemes can be implemented to facilitate bonding to the spacers 32, 34, and 36. Additionally, the spacers 32, 34, and 36 can include a first silver plated surface as an upper surface and a second silver plated surface as a lower surface or a side surface. Although three spacers 32, 34, and 36 are shown in the provided examples, greater than or less than three spacers may be implemented for the coaxial semiconductor package 100 based on the dimensions and weights of the concentric metal contacts 103 and 120. The spacers 32, 34, and 36 can improve mechanical ruggedness and promote double sided cooling for the coaxial semiconductor package 100.

To provide a representative example for the switch modules 22, 24, and 26, the switch module 22 can include a switching transistor 106, a metal interconnect 108, and a coaxial gate interconnect 110. The switching transistor 106 can include a source electrically connected to the metal interconnect 108, a drain electrically connected to the first concentric metal contact 103, and a gate electrically connected to the coaxial gate interconnect 110. The gate of the switching transistor 106 can be electrically connected to the coaxial gate interconnect 110 via a center conductor of the coaxial gate interconnect 110. The coaxial gate interconnect 110 can additionally be electrically connected to the source of the switching transistor 106 via an outer conductor of the coaxial gate interconnect 110. The coaxial gate interconnect 110 can also be electrically connected to the source of the switching transistor 106 to form a kelvin source connection for the gate drive signal. The second concentric metal contact 120 can be electrically connected to the source of the switching transistor 106.

The first concentric metal contact 103 and the second concentric metal contact 120 can both include copper-tungsten or other composites including copper. The first concentric metal contact 103 and the second concentric metal contact 120 are shaped differently. For example, the second concentric metal contact 120 is shaped and designed to be equipped with the PCB slip ring 130 and includes the upper portion 124 and a lower portion 126, with the upper portion 124 having a smaller circumference than a circumference of the lower portion 126. The coaxial semiconductor package 100 includes a hollow portion 150 that is configured to allow passthrough. The first concentric metal contact 103 is shaped and designed to house the switching modules 22, 24, and 26 and the spacers 32, 34, and 36. A circumference of the first concentric metal contact 103 is generally the same as the circumference of the lower portion 126 of the second concentric metal contact 120. However, in some embodiments, the circumference of the first concentric metal contact 103 and the circumference of the lower portion 126 of the second concentric metal contact 120 can be different.

A thickness of the first concentric metal contact 103 is generally different from thicknesses of the upper portion 124 and the lower portion 126 of the second concentric metal contact 120. However, the combined thickness of the upper portion 124 and the lower portion 126 may be substantially similar to the thickness of the first concentric metal contact 103. Upon the bonding of the second concentric metal contact 120 to the metal interconnects of the switch modules 22, 24, and 26, the second concentric metal contact 120 can physically contact and compresses the metal interconnects (e.g., the metal interconnect 108). The concentric metal contacts 103 and 120 can also include nickel (Ni)—Ag plating in some cases and provide reduced thermo-mechanical stress and reduced peak electric field for the coaxial semiconductor package 100 and provides heat spreading for the coaxial semiconductor package 100. The switch modules 22, 24, and 26 and the spacers 32, 34, and 36 are symmetrically arranged along a circumferential direction relative to the circumference of the first concentric metal contact 103. For example, distances between each of the three switch modules 22, 24, and 26 are equidistant or substantially similar in the circumferential direction.

The coaxial gate interconnect 110 (and other coaxial gate interconnects of the switch modules 22, 24, and 26) can be concentric and cylindrical in shape. The coaxial gate interconnect 110 can also include anisotropic conductive film (ACF) and/or a molybdenum post. This post could be made from other materials, such as copper. This component could also be described as a socket, adapter, or mount, etc. The post can be relied upon to provide a solder cup or socket for the coaxial gate interconnect to terminate to on one side, while providing a flat surface for bonding to the die on the other side. The coaxial gate interconnect 110 can be configured to connect to a respective gate driver of a power converter system, for driving and controlling switching operations of the switching transistor 106. The coaxial gate interconnect 110 can connect to a respective gate driver via the slip ring 130, which can be configured to function as an interface for the respective gate driver circuitry. The coaxial gate interconnect 110 can include a combination of: various metals and polytetrafluoroethylene (PTFE), various metals and microporous PTFE, glass and Kovar, and/or AL and CTE-matched epoxy. However, the coaxial gate interconnect 110 is not limited thereto. Benefits of the coaxial gate interconnect 110 include its coaxial structure which allows inductance to scale well with length.

In some examples, the coaxial semiconductor package 100 can be implemented within MV cables for use in electrical distribution networks such as electrical substations, EV charging systems, and renewable energy infrastructure systems, among other distribution networks. The coaxial semiconductor package 100 can preserve a coaxial structure of the MV cable it may be implemented in, utilize solid insulation instead of air, and distribute heat axially to reduce heat flux. For example, the hollow portion 150 can facilitate installation of an MV cable or other coaxial structure. The coaxial semiconductor package 100 is further equipped with a modular architecture, where one or more components may be added or removed depending on application of the coaxial semiconductor package 100. The coaxial semiconductor package 100, via the switch package 140, can facilitate power conversion in a power converter. For example, the coaxial semiconductor package 100 can facilitate direct current (DC)-to-DC conversion, such as from a higher DC voltage at a lower current rating to a lower DC voltage at a higher current rating. Additionally, the coaxial semiconductor package 100 can facilitate bidirectional power conversion for a power converter system in various applications.

The switching transistor 106 can be embodied as a silicon carbide (SiC) metal-oxide-semiconductor-field-effect transistor (MOSFET) preferably for use with MV applications. However, the switching transistor 106 can be embodied as a different type of switch depending on the application of the coaxial semiconductor package 100. For example, the switching transistor 106 can be embodied as a Si insulated gate bipolar transistor (IGBT), among other types of switching transistors, for use with EV charging systems.

The second concentric metal contact 120 can be equipped with the PCB slip ring 130. In the example shown, the PCB slip ring 130 is substantially fitted within the circumference defined by the upper portion 124 of the second concentric metal contact 120. The PCB slip ring 130 can be designed and configured to receive the coaxial gate interconnects (e.g., the coaxial gate interconnect 110) of the switch modules 22, 24, and 26 through one or more receptacles or ports that may be drilled into PCB slip ring 130 and the second concentric metal contact 120. The PCB slip ring 130 is substantially concentric in shape and centrically positioned relative to the second concentric metal contact 120. The PCB slip ring 130 can include axially symmetric electrical contacts. The PCB slip ring 130 can include compliant dry mating contacts (e.g., spring pins, fuzz buttons, wavy washers, etc.) in some cases. Additionally, the PCB slip ring 130 can include axially symmetric electric contacts. The PCB slip ring 130 enables blind electrical connections and built in compliance and is axially symmetric in design.

The wave spring 122 may also be positioned around the upper portion 124 of the second concentric metal contact 120. For example, the wave spring 122 can be substantially fitted around the circumference defined by the upper portion 124 of the second concentric metal contact 120. The wave spring 122 is substantially concentric in design and shape. The wave spring 122 can be used to absorb geometric tolerances, compress drain-side thermal interface material, and provide compressed waves for low contact resistance interface for the coaxial semiconductor package 100.

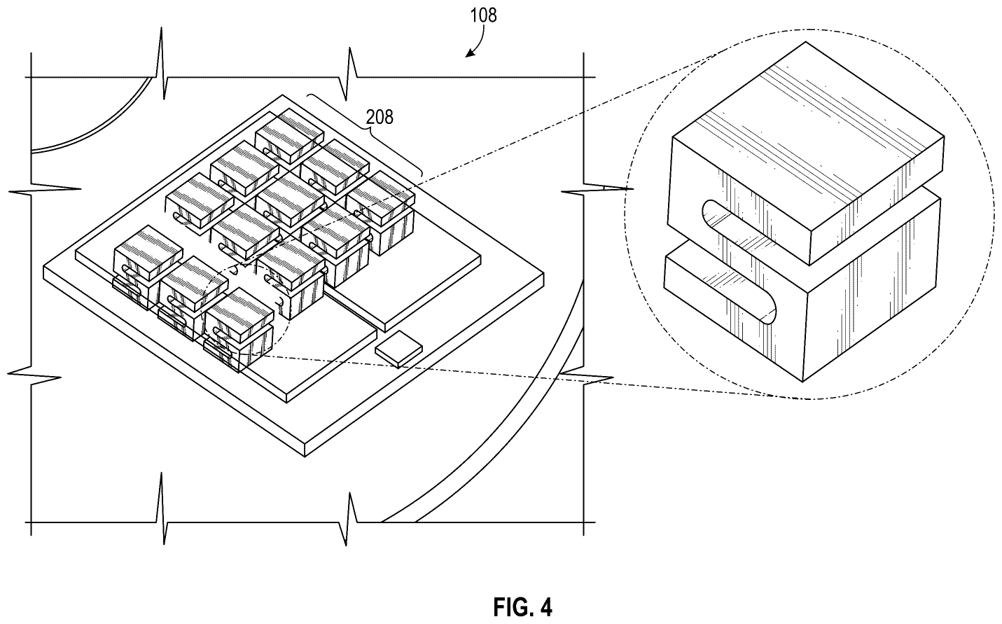

FIG. 4 depicts a perspective view of a metal interconnect used in a switch package shown in FIGS. 2 and 3, according to one or more embodiments of the present disclosure. As mentioned previously, the metal interconnect 108 can be connected to the source of the switching transistor 106. The metal interconnect 108 can include a plurality of compliant copper interconnects 208. The metal interconnect 108 is configured to physically contact the second concentric metal contact 120. For example, the first concentric metal contact 103 can be bonded to the drain side of the die of the switching transistor 106 (and also dies of the other switching transistors of the switch modules 22, 24, and 26) and a lower side of each of the spacers 32, 34, and 36. Additionally, the second concentric metal contact 120 can be bonded to the metal interconnect 108 (and also metal interconnects of the other switch modules 22, 24, and 26) and an upper side of each of the spacers 32, 34, and 36. Each metal interconnect (e.g., the metal interconnect 108) can physically compress based on compressive forces exerted via the second concentric metal contact 120. That is, each of the plurality of compliant copper interconnects 208 can physically compress based on compressive forces exerted via the second concentric metal contact 120.

In the example shown in FIG. 4, the metal interconnect 108 includes twelve (12) compliant copper interconnects, but greater than or less than 12 copper interconnects can be relied upon in some embodiments. Each of the compliant copper interconnects 208 can have a relief cut having a depth determined by a desired stress or deformation behavior. Each of the compliant copper interconnects 208 can also have a flat bonding surface. For example, each of the compliant copper interconnects 208 can include a top flat bonding surface and/or a bottom flat bonding surface. The flat bonding surfaces can have a length or a width determined by tolerable thermomechanical stress caused by CTE mismatch between copper and SiC. The metal interconnect 108 provides multiple benefits such as absorption of stackup tolerances, improvement of yield, and mechanical decoupling, and allows for a fully Ag sintered package.

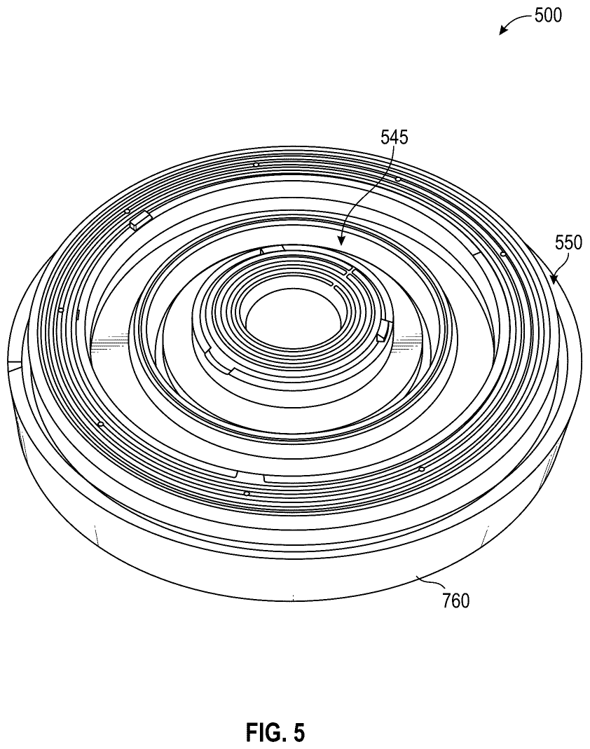

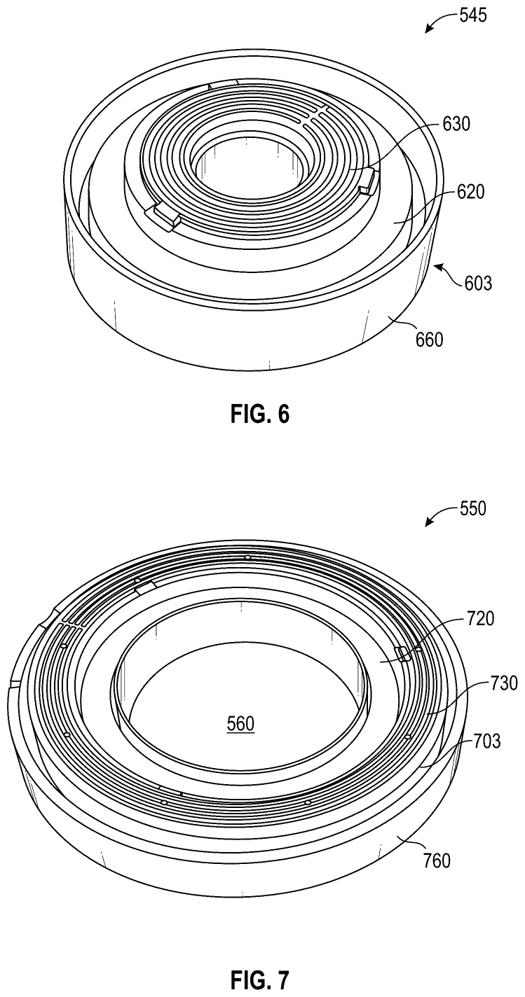

FIG. 5 depicts a perspective view of a nested coaxial semiconductor package 500, FIG. 6 depicts an input semiconductor package of the nested coaxial semiconductor package 500, and FIG. 7 depicts an output semiconductor package of the nested coaxial semiconductor package 500, according to one or more embodiments of the present disclosure. The nested coaxial semiconductor package 500 can include one or more semiconductor packages nested coaxially in various layers together. For example, the nested coaxial semiconductor package 500 can include an input semiconductor package 545 that is coaxially or concentrically nested within an output semiconductor package 550.

The input semiconductor package 545 is similar to or can generally include the coaxial semiconductor package 100. For example, the input semiconductor package 545 can include a PCB slip ring 630, a first concentric metal contact 603, and a second concentric metal contact 620, in a similar stacked arrangement as that of the coaxial semiconductor package 100. The input semiconductor package 545 can include a similar switch arrangement as that shown by the switch package 140, where one or more switch modules can be implemented with the first concentric metal contact 603 (not shown) and a second concentric metal contact 620. A case or protector 660 can be provided around the stacked arrangement of the input semiconductor package 545.

The output semiconductor package 550 includes a similar switch module arrangement or architecture as the input semiconductor package 545 but includes different dimensions for its PCB slip ring 730, first concentric metal contact 703, and second concentric metal contact 720, to accommodate a nested installation of the input semiconductor package 545 within a hollow portion 560. For example, the output semiconductor package 550 can include a similar switch arrangement as that shown by the switch package 140, where one or more switch modules can be implemented with the first concentric metal contact 703 and the second concentric metal contact 720. A case or protector 760 can be provided around the stacked arrangement of the output semiconductor package 550.

The input semiconductor package 545 can be configured to be connected to high voltage potentials in a power converter system, and the output semiconductor package 550 can be configured to be connected to lower voltage potentials of the power converter system.

The above-described features allow voltage distribution in the overall system to replicate that of an MV cable, thus inheriting the voltage scaling properties of MV cables. In one example, the input semiconductor package 545 can be configured to operate at 3.3 kV and 9 mΩ, and the output semiconductor package 550 can be configured to operate at 3.3 kV and 3 mΩ. The nested coaxial semiconductor package 500 can be used for power conversion applications generally anywhere cables may be used, facilitate intelligent cable splice (e.g., low voltage (LV) to MV, DC to alternating current (AC), etc.), and inherit advantages of various types of cables such as voltage scaling and passive cooling.

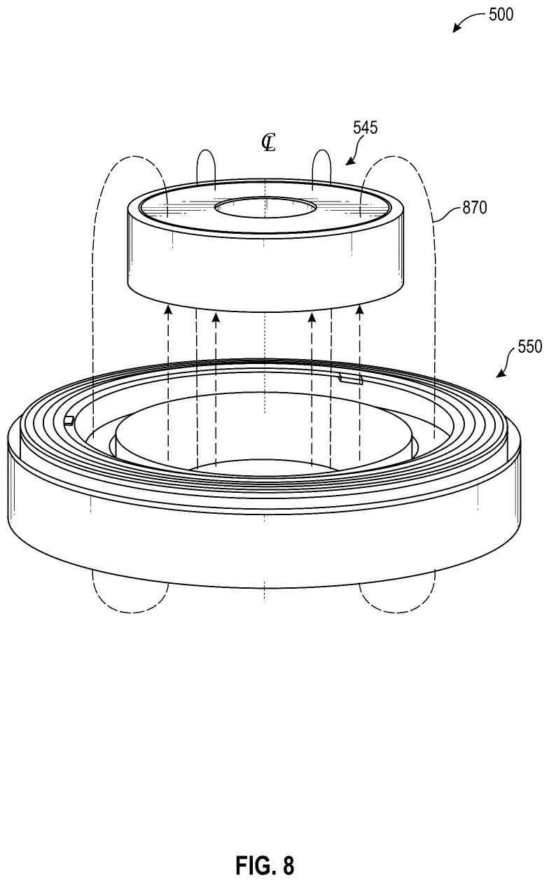

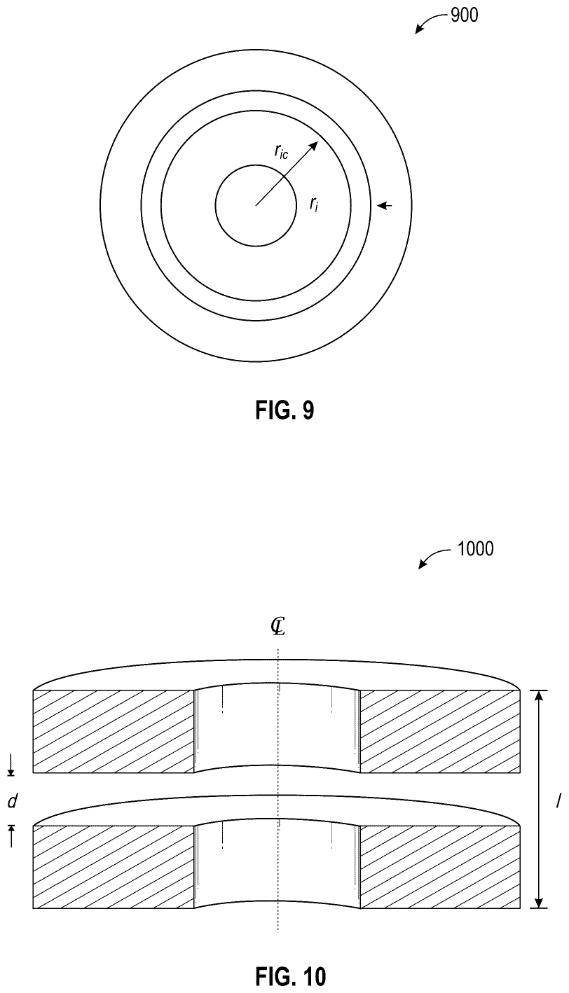

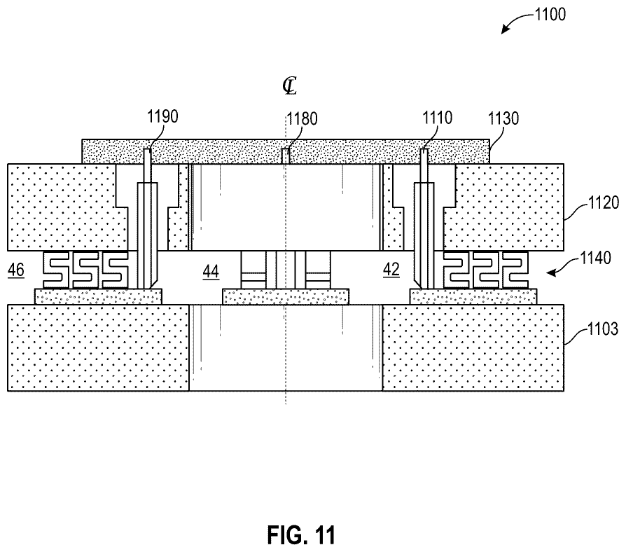

FIG. 8 depicts a coaxial commutation loop in the nested coaxial semiconductor package 500, FIG. 9 depicts an inter-package schematic 900 of the nested coaxial semiconductor package 500, and FIG. 10 depicts an intra-package schematic 1000 of the nested coaxial semiconductor package 500, according to one or more embodiments of the present disclosure. The nested coaxial semiconductor package 500 enables implementation of voltage and current scaling with radius, a coaxial commutation loop, uniform inter-package E-field, uniform temperature distribution, and uniform current sharing, among others. The input semiconductor package 545 and the output semiconductor package 550 can be used in tandem to create a coaxial commutation loop 870. The coaxial commutation loop 870 allows the magnetic fields generated by commutation currents in both switch packages 545 and 550 to tightly couple and cancel, resulting in very low commutation loop inductance (L_{PL}).

The L_{PL} can be derived from the inter-package schematic 900 and the intra-package schematic 1000, where the nested coaxial semiconductor package 500 provides low L_{PL} with high voltage ratings in operation. However, it should be noted that some potential challenges with the nested coaxial semiconductor package 500 include gate driver integration, axial mechanical loading, and implementation of vertical interconnects.

FIG. 11 depicts a schematic of a coaxial semiconductor package 1100 that can be implemented in the nested coaxial semiconductor package 500, according to one or more embodiments of the present disclosure. The coaxial semiconductor package 1100 can be representative of either the input semiconductor package 545 or the output semiconductor package 550. The coaxial semiconductor package 1100 includes a first concentric metal contact 1103, a second concentric metal contact 1120, and a PCB slip ring 1130. The first concentric metal contact 1103 can house a switch package 1140, which can be similar to the switch package 140. The switch package 1140 includes switch modules 42, 44, and 46, and each of the switch modules 42, 44, and 46 includes a coaxial gate interconnect to connect a die of a respective switch module to a gate driver interface on the PCB slip ring 1130. For example, the switch module 42 includes a coaxial gate interconnect 1110 for connecting a die of the switch module 42 to the gate driver interface on the PCB slip ring 1130, the switch module 44 includes a coaxial gate interconnect 1180 for connecting a die of the switch module 44 to the gate driver interface on the PCB slip ring 1130, and the switch module 46 includes a coaxial gate interconnect 1190 for connecting a die of the switch module 46 to the gate driver interface on the PCB slip ring 1130.

Each of the coaxial gate interconnects 1110, 1180, and 1190 are vertical gate/kelvin interconnects and are generally long enough in length to extend from the dies of the switch modules 42, 44, and 46 to the gate driver interface on the PCB slip ring 1130. The coaxial gate interconnects 1110, 1180, and 1190 have low gate loop inductance and low mutual inductance between the gate driver interface and various power loops between the gate driver interface and the switch package 1140.

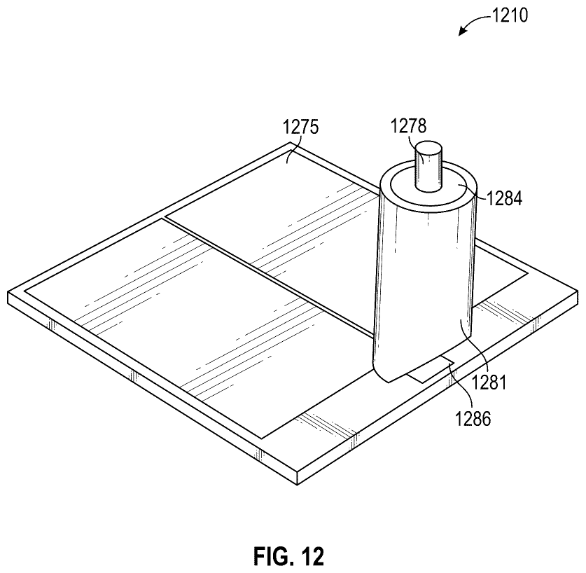

FIG. 12 depicts a perspective view of a coaxial gate interconnect 1210 according to one or more embodiments of the present disclosure. The coaxial gate interconnect 1210 is a coaxial gate interconnect that can be implemented in the coaxial semiconductor package 100 or the nested coaxial semiconductor package 500. The coaxial gate interconnect 1210 can be connected between a die 1275 and the gate driver interface on the PCB slip ring 130, the gate driver interface on the PCB slip ring 630, or the gate driver interface on the PCB slip ring 730. The coaxial gate interconnect 1210 can include a molybdenum post 1286 as part of a mechanical bonding or electrical connection process for connection of the coaxial gate interconnect 1210 to the die 1275. Generally, the molybdenum post 1286 can be made from other materials, such as copper. The molybdenum post 1286 can also be represented as a socket, adapter, or mount, etc. The molybdenum post 1286 can be relied upon to provide a solder cup or socket for the coaxial gate interconnect 1210 to terminate on one side, while providing a flat surface for bonding to the die 1275 on the other side.

A gate 1278 of a switching transistor that is implemented on the die 1275 can be connected to the gate driver interface implemented on the PCB slip ring 130, 630, or 730 via the coaxial gate interconnect 1210. A kelvin source connection 1281 can be formed around the gate 1278 to drive a gate drive signal. The coaxial gate interconnect 1210 can include ACF 1284 surrounding the gate 1278, which can provide a single bond for gate and kelvin connections and high bond strength.

The coaxial arrangement and rotational symmetry of the two power semiconductor packages 545 and 550 allow for good current sharing among parallel die and low commutation loop inductances, indicating that the nested coaxial semiconductor package 500 can be scaled to higher voltages without paying an inductance penalty.

Various embodiments pertaining to coaxial semiconductor packages have been described. In particular, nested coaxial semiconductor packages can provide voltage and current scale with radius, coaxial commutation loop, uniform inter-package E-field, uniform temperature distribution, and/or uniform current sharing. These semiconductor packages can be used for power conversion applications generally anywhere a cable may be present, facilitate intelligent cable splicing (e.g., low voltage (LV) to MV, DC to alternating current (AC), etc.), and inherit advantages of cables such as voltage scaling and passive cooling.

The coaxial semiconductor packages of the embodiments can include many benefits over conventional semiconductor packages that may be incorporated within MV cables, such as inclusion of thermo-mechanical and mechanically rugged features, which can enable the coaxial semiconductor packages to withstand and survive high temperatures and mechanical stress such as axial loading. The coaxial semiconductor packages of the embodiments can further allow for seamless integration with MV cables and provide benefits such as balanced current distribution, axially symmetric heat distribution, and reduced peak electric field intensity.

The features, structures, and components described above may be combined in one or more embodiments in any suitable manner, and the features discussed in the various embodiments are interchangeable, where technically suitable. In the foregoing description, certain details provided convey the concepts of the present disclosure. However, a person skilled in the art will appreciate that the technical solution of the present disclosure may be practiced without one or more of the specific details, or other methods, components, materials, and the like may be employed. In other instances, well-known structures, materials, or operations are not shown or described in detail to avoid obscuring aspects of the present disclosure.

Although relative terms such as “on,” “below,” “upper,” “lower,” “top,” “bottom,” “right,” and “left” may be used to describe the relative spatial relationships of certain structural features, these terms are used for convenience only, as a direction in the examples. It should be understood that if the device is turned upside down, the “upper” component will become a “lower” component. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified.

Combinatorial language, such as “at least one of X, Y, and Z” or “at least one of X, Y, or Z,” unless indicated otherwise, is used in general to identify one, a combination of any two, or all three (or more if a larger group is identified) thereof, such as X and only X, Y and only Y, and Z and only Z, the combinations of X and Y, X and Z, and Y and Z, and all of X, Y, and Z. Such combinatorial language is not generally intended to, and unless specified does not, identify or require at least one of X, at least one of Y, and at least one of Z to be included. The terms “about” and “substantially,” unless otherwise defined herein to be associated with a particular range, percentage, or related metric of deviation, account for at least some manufacturing tolerances between a theoretical design and manufactured product or assembly, such as the geometric dimensioning and tolerancing criteria described in the American Society of Mechanical Engineers (ASME®) Y14.5 and the related International Organization for Standardization (ISO®) standards. Such manufacturing tolerances are still contemplated, as one of ordinary skill in the art would appreciate, although “about,” “substantially,” or related terms are not expressly referenced, even in connection with the use of theoretical terms, such as the geometric “perpendicular,” “orthogonal,” “vertex,” “collinear,” “coplanar,” and other terms.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

1. A coaxial semiconductor package, comprising:
a first concentric metal contact;
a plurality of switching transistors arranged concentrically at and around the first concentric metal contact, a switching transistor of the plurality of switching transistors comprising:
a source coupled to a metal interconnect;
a drain coupled to the first concentric metal contact; and
a gate coupled to a coaxial gate interconnect, the coaxial gate interconnect configured to couple the switching transistor to a gate driver of a power converter system; and
a second concentric metal contact coupled to the source.

2. The coaxial semiconductor package of claim 1, further comprising:
a printed circuit board (PCB) slip ring positioned within the second concentric metal contact and configured to receive the coaxial gate interconnect, the PCB slip ring comprising the gate driver.

3. The coaxial semiconductor package of claim 2, wherein:
the PCB slip ring is concentric in shape and centrically positioned relative to the second concentric metal contact;
the PCB slip ring comprises axially symmetric electrical contacts; and/or
the PCB slip ring comprises compliant dry mating contacts.

4. The coaxial semiconductor package of claim 1, further comprising:
a plurality of spacers arranged concentrically at and around the first concentric metal contact, the plurality of spacers configured to adjust a height between the first concentric metal contact and the second concentric metal contact.

5. The coaxial semiconductor package of claim 4, wherein each of the plurality of spacers comprises aluminum nitride (AlN).

6. The coaxial semiconductor package of claim 4, wherein:
each of the plurality of spacers is between at least two switching transistors of the plurality of switching transistors.

7. The coaxial semiconductor package of claim 1, wherein the metal interconnect contacts the second concentric metal contact.

8. The coaxial semiconductor package of claim 7, wherein the metal interconnect is configured to compress based on the contact, the contact occurring based on a force applied to the second concentric metal contact.

9. The coaxial semiconductor package of claim 1, wherein the metal interconnect comprises a plurality of compliant copper interconnects.

10. The coaxial semiconductor package of claim 9, wherein each of the plurality of compliant copper interconnects comprises:
a relief cut having a depth determined by a desired stress or deformation behavior; and
a flat bonding surface.

11. The coaxial semiconductor package of claim 1, wherein:
the first concentric metal contact is bonded to the drain based on a sintering process; and
the second concentric metal contact is bonded to the metal interconnect based on a sintering process.

12. The coaxial semiconductor package of claim 1, wherein the first concentric metal contact and the second concentric metal contact each comprises copper-tungsten.

13. The coaxial semiconductor package of claim 1, wherein the coaxial gate interconnect is concentric in shape and comprises:
anisotropic conductive film (ACF) as part of a mechanical bonding or electrical connection process for connection of the coaxial gate interconnect to a die of the switching transistor.

14. The coaxial semiconductor package of claim 1, wherein the plurality of switching transistors is symmetrically arranged along a circumferential direction relative to a circumference of the first concentric metal contact.

15. The coaxial semiconductor package of claim 1, wherein the switching transistor is a silicon carbide (SiC) metal-oxide-semiconductor-field-effect transistor (MOSFET).

16. A nested coaxial semiconductor package, comprising:
an input semiconductor package configured to be connected to high voltage potentials in a power converter system; and
an output semiconductor package configured to be connected to lower voltage potentials in the power converter system, wherein the input semiconductor package is nested within the output semiconductor package.

17. The nested coaxial semiconductor package of claim 16, wherein the input semiconductor package or the output semiconductor package comprises a switch package, the switch package comprising a plurality of switch modules, a switch module of the plurality of switch modules comprising:
a switching transistor on a first concentric metal contact;
a coaxial gate interconnect configured to couple the switching transistor to a gate driver of a power converter system; and
a metal interconnect configured to physically compress based on a force applied by a second concentric metal contact.

18. The nested coaxial semiconductor package of claim 17, wherein the switch package comprises:
a spacer between at least two switch modules of the plurality of switch modules, the spacer comprising aluminum nitride (AlN).

19. The nested coaxial semiconductor package of claim 17, further comprising:
a printed circuit board (PCB) slip ring positioned at the second concentric metal contact and configured to receive the coaxial gate interconnect, the PCB slip ring comprising the gate driver.

20. The nested coaxial semiconductor package of claim 17, wherein the plurality of switch modules is symmetrically arranged along a circumferential direction relative to a circumference of the first concentric metal contact.
